(19) United States
(12) Patent Application Publication
(10) Pub. No.: US 2019/0264076 A1
(43) Pub. Date: Aug. 29, 2019

(54) ADHESION LAYER-FORMING COMPOSITION AND METHOD FOR PRODUCING ARTICLE

(71) Applicant: CANON KABUSHIKI KAISHA, Tokyo (JP)

(72) Inventors: Masayuki Tanabe, Utsunomiya-shi (JP); Toshiki Ito, Kawasaki-shi (JP)

(21) Appl. No.: 16/411,636

(22) Filed: May 14, 2019

Related U.S. Application Data
(63) Continuation of application No. PCT/JP2017/040737, filed on Nov. 13, 2017.

(30) Foreign Application Priority Data
Nov. 16, 2016 (JP) 2016-223346

(51) Int. Cl. C09J 133/14; C09J 11/06; C09J 171/02; G03F 7/00; G03F 7/11; G03F 7/34

(52) U.S. Cl. CPC C09J 133/14; C09J 11/06; C09J 171/02; C08K 5/357; G03F 7/11; G03F 7/34; G03F 7/0002

(57) ABSTRACT

An adhesion layer-forming composition to allow a substrate to adhere to a photocurable composition at least contains a curable base material (A) containing at least one functional group that binds to a base and at least one radically polymerizable functional group, a polymerization inhibitor (B), and an organic solvent (C), the adhesion layer-forming composition having a polymerization inhibitor (B) content of 0.1 parts by weight or more and 20 parts by weight or less based on 100 parts by weight of the curable base material (A).

### CROSS-REFERENCE TO RELATED APPLICATIONS

This application is a Continuation of International Patent Application No. PCT/JP2017/040737, filed Nov. 13, 2017, which claims the benefit of Japanese Patent Application No. 2016-223346, filed Nov. 16, 2016, both of which are hereby incorporated by reference herein in their entirety.

### TECHNICAL FIELD

The present invention relates to an adhesion layer-forming composition and a method for producing an article.

### BACKGROUND ART

Photo-imprint techniques have been receiving attention as techniques for producing articles, such as semiconductor devices and microelectromechanical systems (MEMSs), having microstructures. A method for forming a pattern by such a photo-imprint technique may include a placement step, a contact step, a curing step, and a separation step (release step). In the placement step, a photocurable composition is placed in a pattern formation region on a base. In the contact step, the photocurable composition is formed with a mold including a pattern. In the curing step, the photocurable composition is cured by irradiating the photocurable composition with light to form a cured product. In the separation step, the mold is separated from the cured product of the photocurable composition. Thereby, the cured product having a pattern transferred from the mold is provided on the base.

In the method for forming a pattern by the photo-imprint technique, the adhesion between the photocurable composition and the base is important. This is because if the adhesion between the photocurable composition and the base is low, a portion of the cured product is peeled from the base when the mold is separated from the cured product of the photocurable composition in the separation step, thereby resulting in a missing portion of the pattern.

Hitherto, as a technique for improving the adhesion between a photocurable composition and a base, a technique for forming an adhesion layer that is located between the photocurable composition and the base and that allows the photocurable composition to adhere to the base has been reported (PTLs 1 and 2).

### CITATION LIST

### Patent Literature

PTL 1 Japanese Patent No. 5084728

PTL 2 Japanese Patent Laid-Open No. 2016-28419

If particles are present on a substrate on which an adhesion layer is disposed, a pattern formed by an imprint technique may have defects due to insufficient filling and an uneven thickness because of these particles. The defects due to insufficient filling may be caused by curing a photocurable composition while the photocurable composition is not sufficiently filled into a recessed portion included in the pattern of a mold. The uneven thickness refers to non-uniformity in the thickness of the cured product of the photocurable composition and may be caused, for example, by the deformation of the mold or the non-parallelism of a base with the mold due to the presence of the particles. If the particles on the substrate attach to the mold, the shape of the mold may be permanently deformed, or the mold may be broken.

In the case where the adhesion layer is formed on the base, a component to be formed into the adhesion layer can spontaneously undergo a polymerization reaction in an adhesion layer solution (adhesion layer composition) used to form the adhesion layer, thereby possibly forming the particles.

The present invention provides an adhesion layer composition that is advantageous in reducing the formation of particles due to a spontaneous polymerization reaction.

### SUMMARY OF INVENTION

One aspect of the present invention provides an adhesion layer-forming composition to allow a substrate to adhere to a photocurable composition, the adhesion layer-forming composition at least including a curable base material (A) containing at least one functional group that binds to a base and at least one radically polymerizable functional group, a polymerization inhibitor (B), and an organic solvent (C), the adhesion layer-forming composition having a polymerization inhibitor (B) content of 0.1 parts by weight or more and 20 parts by weight or less based on 100 parts by weight of the curable base material (A).

Further features of the present invention will become apparent from the following description of exemplary embodiments with reference to the attached drawings.

### BRIEF DESCRIPTION OF DRAWINGS

FIGS. 1A and 1B illustrate a curable base material (A).

FIGS. 2A to 2C illustrate a curable base material (A).

FIG. 3A illustrates a method for forming a pattern or a method for producing an article.

FIG. 3B illustrates the method for forming a pattern or the method for producing an article.

FIG. 3C illustrates the method for forming a pattern or the method for producing an article.

FIG. 3D illustrates the method for forming a pattern or the method for producing an article.

FIG. 3E illustrates the method for forming a pattern or the method for producing an article.

FIG. 3F illustrates the method for forming a pattern or the method for producing an article.

FIG. 3G illustrates the method for forming a pattern or the method for producing an article.

FIG. 3H illustrates the method for forming a pattern or the method for producing an article.

FIG. 3I illustrates the method for forming a pattern or the method for producing an article.

FIG. 4 is a schematic diagram of an attenuated total reflection infrared spectrometer including a light irradiation portion.

FIG. 5 illustrates the relationship between the amount of a polymerization inhibitor and the relative particle formation rate.

### DESCRIPTION OF EMBODIMENTS

Embodiments of the present invention will be described in detail below. The present invention is not limited to the following embodiments. Various modifications and improvements of the following embodiments are also included in the scope of the present invention without departing from the spirit thereof on the basis of the usual knowledge of those skilled in the art.

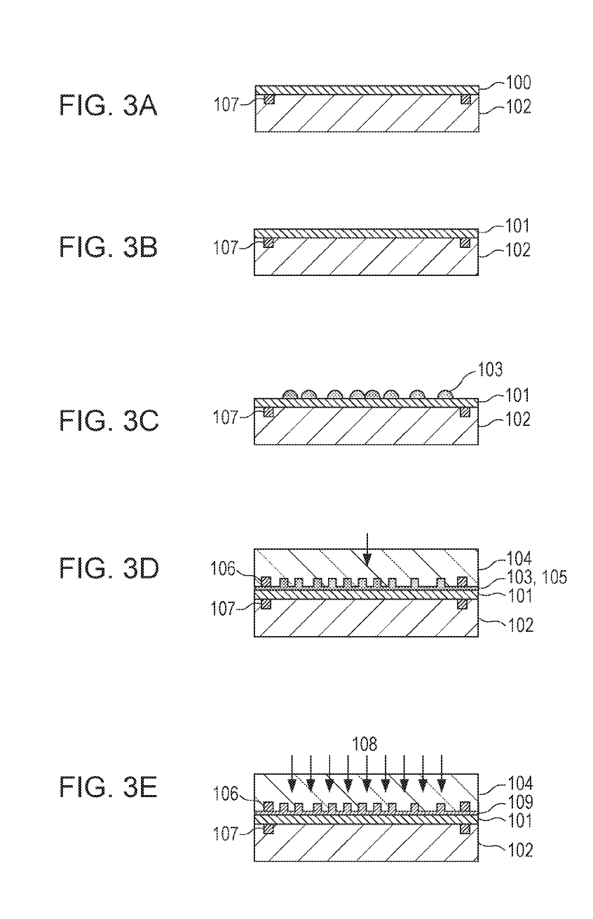

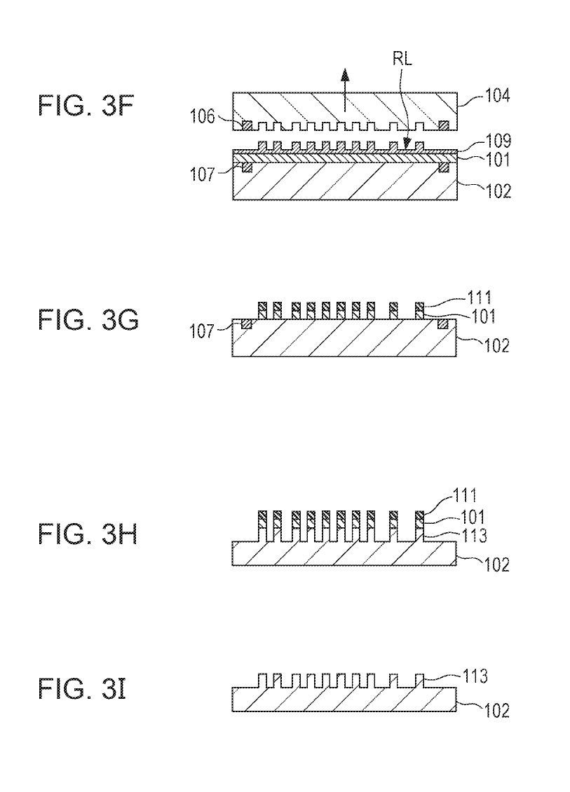

A method for forming a pattern or a method for producing an article according to an embodiment of the present invention will be described below with reference to FIG. 3. In the method for forming a pattern or the method for producing an article, a pattern is formed by an imprint technique. FIGS. 3A and 3B schematically illustrate adhesion layer formation step. In an application step illustrated in FIG. 3A, an adhesion layer-forming composition 100 is applied (disposed) to a base 102, which is formed of a semiconductor substrate. The base 102 may have marks 107. In a heating step illustrated in FIG. 3B, the adhesion layer-forming composition 100 is cured by heating to form an adhesion layer 101.

In a placement step illustrated in FIG. 3C, a photocurable composition 103 is placed on the adhesion layer 101. In a contact step illustrated in FIG. 3D, a mold 104 is brought into contact with the photocurable composition 103. The mold 104 includes a pattern of a recessed portion in a pattern region thereof. When the pattern region of the mold 104 is brought into contact with the photocurable composition 103, the photocurable composition 103 is filled into the recessed portion of the recessed portion and a protruding portion constituting the pattern of the mold 104 and spreads between the adhesion layer 101 and the mold 104. This step is a step of forming the photocurable composition 103 with the mold 104.

In a curing step illustrated in FIG. 3E, the photocurable composition 103 is cured by irradiating the photocurable composition 103 with light to form a cured product 109. In a separation step (release step) illustrated in FIG. 3F, the mold 104 is separated from the cured product 109. The cured product 109 has a protruding portion and a recessed portion corresponding to the recessed portion and the protruding portion constituting the pattern of the mold 104. More specifically, the cured product 109 has the protruding portion corresponding to the recessed portion of the pattern of the mold 104 and the recessed portion corresponding to the protruding portion of the pattern of the mold 104.

In a residual layer removal step illustrated in FIG. 3G, the cured product 109 and the adhesion layer 101 are etched so as to expose the adhesion layer 101 below the recessed portion of the cured product 109 and then expose the base 102, thereby leaving a cured product pattern 111 corresponding to the protruding portion of the cured product 109 and the adhesion layer 101 under the cured product pattern 111. In this way, an article including the cured product pattern 111 can be produced.

In a processing step schematically illustrated in FIG. 3H, the base 102 may be etched using the cured product pattern 111 as a mask, or ions may be implanted into the base 102. In an example where the base 102 is etched, a portion of the base 102 to be etched may be the semiconductor substrate or may be a layer such as a conductive layer or an insulating layer disposed on the semiconductor substrate. By etching the base 102, a pattern structure 113 can be formed.

After the processing step illustrated in FIG. 3H, the base 102 can be further processed to form a semiconductor device substrate including at least one semiconductor chip. The semiconductor device substrate can be subjected to dicing to form the semiconductor chip. The semiconductor chip can be mounted on a wiring board such as a PCB to produce an electronic device.

The adhesion layer-forming composition 100 is a composition to be formed into the adhesion layer 101 that allows the base 102 to adhere to the photocurable composition 103. The adhesion layer-forming composition 100 at least contains a curable base material (A) containing at least one functional group that binds to the base 102 and at least one radically polymerizable functional group, a polymerization inhibitor (B), and an organic solvent (C). The polymerization inhibitor (B) content is 0.1 parts by weight or more and 20 parts by weight or less, preferably 0.2 parts by weight or more and 10 parts by weight or less based on 100 parts by weight of the curable base material (A).

The adhesion layer-forming composition 100 is disposed on the base 102 and then cured to form the adhesion layer 101. A stack including the base 102 and the adhesion layer 101 formed by curing the adhesion layer-forming composition 100 on the base 102 is useful to obtain the cured product 109 including the photocurable composition 103 placed on the stack. The adhesion layer-forming composition 100 is useful as an underlying material for a curable composition (for imprinting), in particular, the photocurable composition 103, used to form a pattern by an imprint technique.

Components contained in the adhesion layer-forming composition 100 according to the embodiment will be described in detail below.

Curable Base Material (A)

The curable base material (A) according to the embodiment may contain at least one functional group that binds to the base 102 and at least one radically polymerizable functional group that binds to the photocurable composition 103. The term “functional group that binds to” used here refers to a functional group that forms a chemical bond such as a covalent bond, an ionic bond, a hydrogen bond, or a intermolecular force.

The curable base material (A) may contain, as a functional group that binds to the base 102, at least one functional group selected from a hydroxy group, a carboxy group, a thiol group, an amino group, an epoxy group, and a (blocked)isocyanate group.

The curable base material (A) may contain an ethylenically unsaturated group serving as a radically polymerizable functional group. The type of the ethylenically unsaturated group is not particularly limited as long as it is a functional group that binds to the photocurable composition 103, and can be appropriately selected in accordance with the composition of the photocurable composition 103. As the ethylenically unsaturated group of the curable base material (A), a group that easily forms a covalent bond with the photocurable composition 103 is preferably selected. In this case, a strong bond between the adhesion layer 101 and the photocurable composition 103 can be formed.

Examples of the ethylenically unsaturated group include a vinyl group, an allyl group, and a (meth)acryloyl group. The term “(meth)acryloyl group” used in this specification refers to an acryloyl group or a methacryloyl group having an alcohol residue equivalent to that thereof.

The curable base material (A) can form a chemical bond such as a covalent bond, an ionic bond, a hydrogen bond, or an intermolecular force using a functional group present on a surface of the base 102 in the step of heating the adhesion layer-forming composition 100 to form the adhesion layer 101. This can improve the adhesion between the adhesion layer 101 and the base 102. The curable base material (A) can undergo a radical reaction to form a covalent bond with a polymerizable compound in the photocurable composition 103 in the step of curing the photocurable composition 103 to form the cured product 109. This can form a bond between the adhesion layer 101 and the photocurable composition 103 to improve the adhesion between the adhesion layer 101 and the cured product 109 obtained by curing the photocurable composition 103.

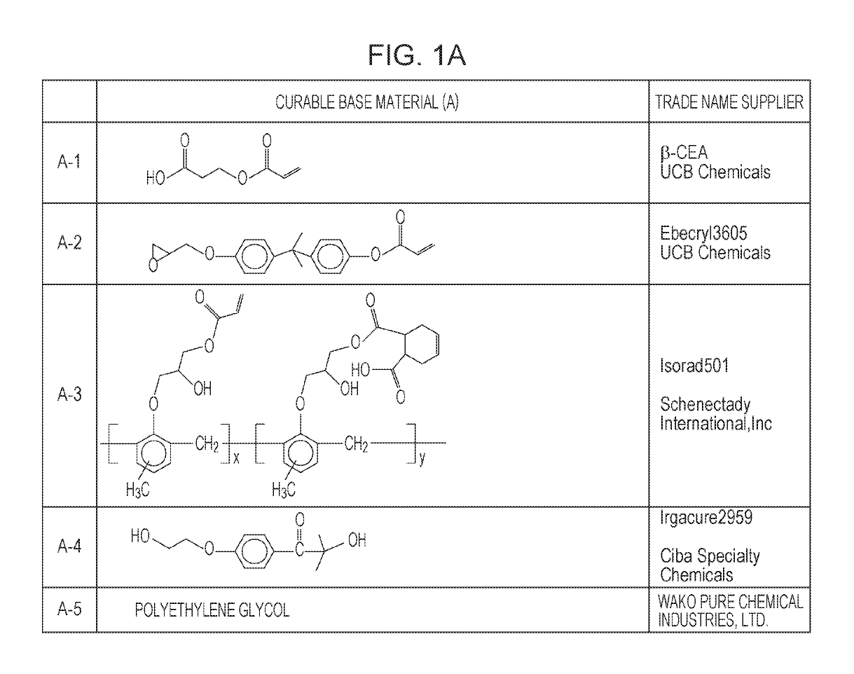

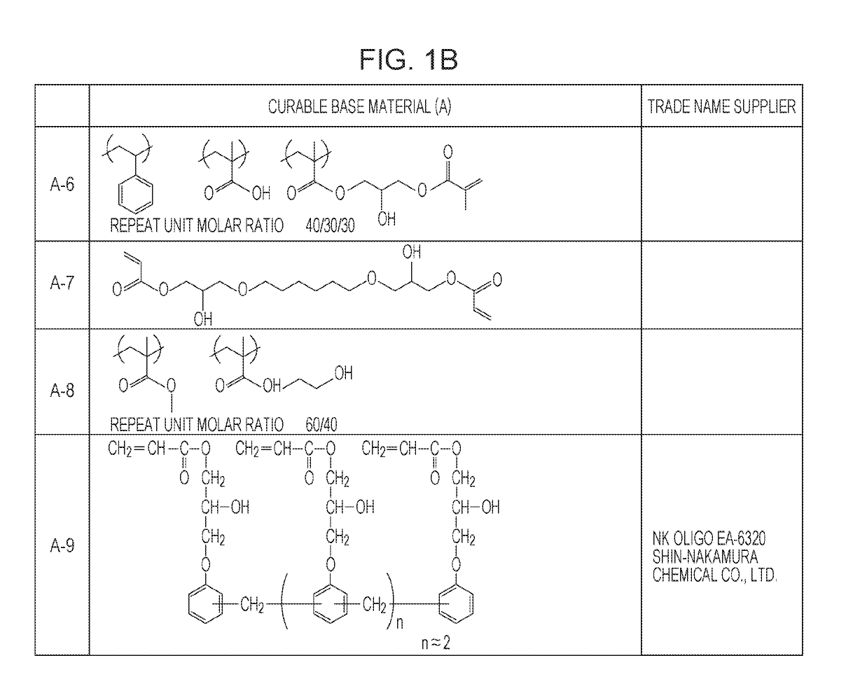

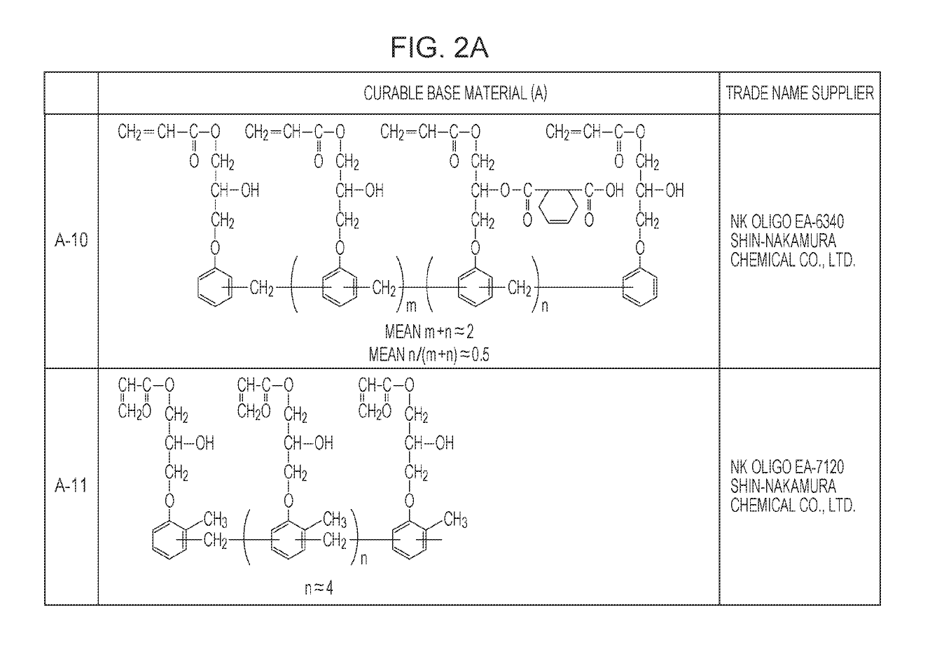

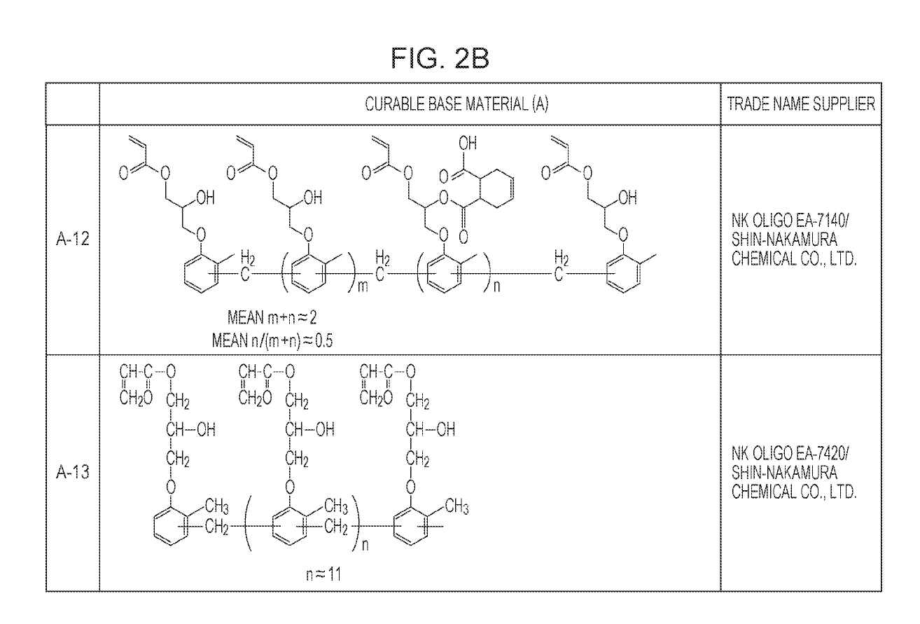

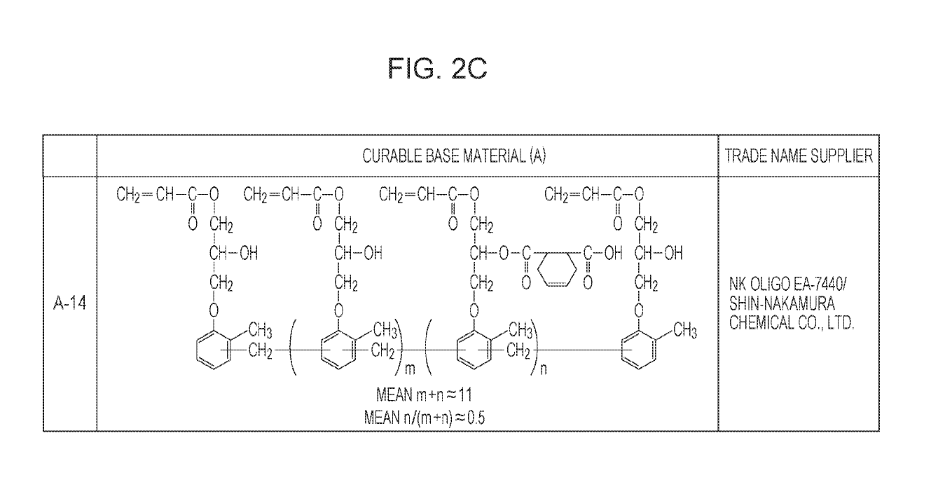

As examples of a material that can be used as the curable base material (A), materials A-1 to A-14 are illustrated in FIGS. 1A to 2C.

Polymerization Inhibitor (B)

The polymerization inhibitor (B) according to the embodiment is a compound having the ability to trap radicals generated in the curable base material (A) before the occurrence of the propagation reaction of the radicals. Thus, the polymerization inhibitor (B) acts to inhibit the polymerization of the curable base material (A).

The polymerization inhibitor (B) may be one selected from hydroquinones, catechols, phenothiazine, and phenoxazine. Specific examples of the polymerization inhibitor (B) include phenolic compounds such as 4-methoxyphenol, 4-methoxy-1-naphthol, 4-tert-butylcatechol, 2,6-di-tert-butylphenol, 2,6-di-tert-butyl-p-cresol, 2-tert-butyl-4,6-dimethylphenol, 2,4,6-tri-tert-butylphenol, hydroquinone, and tert-butylhydroquinone. Specific examples of the polymerization inhibitor (B) also include quinone-based compounds such as naphthoquinone and benzoquinone. Specific examples of the polymerization inhibitor (B) also include amine-based compounds such as phenothiazine, phenoxazine, and 4-hydroxy-2,2,6,6-tetramethylpiperidine. Specific examples of the polymerization inhibitor (B) also include N-oxyl-based compounds such as 2,2,6,6-tetramethylpiperidine-N-oxyl and 4-hydroxy-2,2,6,6-tetramethylpiperidine-N-oxyl. These compounds listed here are mere examples. The polymerization inhibitor (B) may be another compound.

Preferably, the polymerization inhibitor (B) does not volatilize from the adhesion layer-forming composition 100 while being stored at room temperature and volatilizes in the heating step (for example, at 140° C. or higher and 250° C. or lower) in the adhesion layer formation step.

Organic Solvent (C)

The adhesion layer-forming composition 100 according to the embodiment contains an organic solvent (C). The incorporation of the organic solvent (C) in the adhesion layer-forming composition 100 enables a reduction in the viscosity of the adhesion layer-forming composition 100. This results in an improvement in the coating properties of the adhesion layer-forming composition 100 on the base 102.

The organic solvent (C) is not particularly limited as long as it dissolves the curable base material (A) and the polymerization inhibitor (B), and is preferably an organic solvent having a boiling point of 80° C. to 200° C. at atmospheric pressure. The organic solvent (C) preferably contains at least one of a hydroxy group, an ether moiety, an ester moiety, and a ketone moiety. The organic solvent has, for example, good dissolvability for the curable base material (A) and the polymerization inhibitor (B) and good wettability for the base 102.

Specific examples of the organic solvent (C) include alcoholic solvents such as propyl alcohol, isopropyl alcohol, and butyl alcohol. Specific examples of the organic solvent (C) also include ether-based solvents such as ethylene glycol monomethyl ether, ethylene glycol dimethyl ether, ethylene glycol monoethyl ether, ethylene glycol diethyl ether, ethylene glycol monobutyl ether, and propylene glycol monomethyl ether. Specific examples of the organic solvent (C) also include ester-based solvents such as butyl acetate, ethylene glycol monoethyl ether acetate, ethylene glycol monobutyl ether acetate, propylene glycol monomethyl ether acetate, and ethyl lactate. Specific examples thereof also include ketone-based solvents such as methyl isobutyl ketone, diisobutyl ketone, cyclohexanone, 2-heptanone, and γ-butyrolactone. The organic solvent (C) may be a mixture of two or more organic solvents selected from the foregoing options. Among the foregoing options, the organic solvent (C) is particularly preferably propylene glycol monomethyl ether acetate or a mixed solution thereof in view of coating properties.

The percentage of the organic solvent (C) incorporated in the adhesion layer-forming composition 100 can be appropriately adjusted by, for example, the viscosity and the coating properties of the curable base material (A) and the polymerization inhibitor (B) and the thickness of the adhesion layer 101 to be formed. The percentage of the organic solvent (C) incorporated in the adhesion layer-forming composition 100 is preferably 70% by mass or more, more preferably 90% by mass or more, even more preferably 95% by mass or more based on the total weight of the adhesion layer-forming composition 100. A higher percentage of the organic solvent (C) incorporated in the adhesion layer-forming composition 100 results in a smaller thickness of the adhesion layer 101 to be formed; thus, the adhesion layer-forming composition is preferred as an adhesion layer-forming composition used for imprinting. If the percentage of the organic solvent (C) incorporated in the adhesion layer-forming composition 100 is less than 70% by mass, sufficient coating properties cannot be provided, in some cases.

Crosslinker (D)

The adhesion layer-forming composition 100 according to the embodiment may contain a crosslinker (D). The crosslinker (D) is a material that induces a crosslinking reaction for bonding the molecules of the curable base material (A) together (for crosslinking the curable base material (A)) to form a crosslinked structure under heating conditions. Preferably, the crosslinker (D) also has the function of reacting with the polymerization inhibitor (B) in the heating step in the adhesion layer formation step to eliminate the polymerization inhibiting effect of the polymerization inhibitor (B).

The crosslinker (D) may be any material capable of crosslinking the curable base material (A) in the heating step in the adhesion layer formation step and is not particularly limited. Examples of the crosslinker (D) include melamine-based compounds such as pentamethoxymethylmelamine, hexamethoxymethylmelamine, (hydroxymethyl)pentakis(methoxymethyl)melamine, hexaethoxymethylmelamine, hexabutoxymethylmelamine, pentamethylolmelamine, and hexamethylolmelamine. Examples of the crosslinker (D) also include methylated urea-based compounds such as tetrakis(methoxymethyl)glycoluryl, 4,5-dimethoxy-1,3-bis(methoxymethyl)imidazolidin-2-one, tetrakis(butoxymethyl)glycoluryl, tetrakis(ethoxymethyl)glycoluryl, tetrakis(isopropoxymethyl)glycoluryl, tetrakis(amyloxymethyl)glycoluryl, and tetrakis(hexoxymethyl)glycoluryl.

Another Component (E)

The adhesion layer-forming composition 100 according to the embodiment may contain another component (E), depending on various purposes, in addition to the curable base material (A), the polymerization inhibitor (B), the solvent (C), and the crosslinker (D) to the extent that the advantageous effects of the present invention are not impaired. Examples of such another component include surfactants, catalytic polymer components, and antioxidants.

Viscosity of Adhesion Layer-Forming Composition

The viscosity of the adhesion layer-forming composition 100 according to the embodiment at 23° C. varies depending on the types and percentages of, for example, the curable base material (A), the polymerization inhibitor (B), and the solvent (C) incorporated and is preferably 0.5 mPa·s or more and 20 mPa·s or less, more preferably 1 mPa·s or more and 10 mPa·s or less, even more preferably 1 mPa·s or more and 5 mPa·s or less.

In the case where the adhesion layer-forming composition 100 has a viscosity of 20 mPa·s or less, the adhesion layer-forming composition 100 has good coating properties on the base 102. It is thus possible to easily control the thickness of the adhesion layer-forming composition 100 on the base 102.

Impurity Mixed in Adhesion Layer-Forming Composition

Impurities in the adhesion layer-forming composition 100 according to the embodiment are preferably minimized. The term “impurities” used here refers to substances other than the curable base material (A), the polymerization inhibitor (B), the solvent (C), the crosslinker (D), or another component (E).

Thus, the adhesion layer-forming composition 100 according to the embodiment is preferably obtained through a purification process. A preferred example of the purification process is filtration with a filter. In the case of the filtration with a filter, specifically, after the curable base material (A), the polymerization inhibitor (B), the solvent (C), and the crosslinker (D) and the another component (E), which are added as needed, are mixed together, the mixture is preferably filtered through a filter having a pore size of, for example, 0.001 μm or more and 5.0 μm or less. In the case where the filtration with the filter is performed, the filtration is more preferably performed in multiple stages or repeated many times. The resulting filtrate may be filtered again. The filtration may be performed with multiple filters having different pore sizes. Examples of the filter used for the filtration include, but are not particularly limited to, polyethylene resin filters, polypropylene resin filters, fluororesin filters, and nylon resin filters.

Impurities such as particles mixed in the adhesion layer-forming composition 100 can be removed through the purification process. This makes it possible to prevent the occurrence of unintentional defects in the adhesion layer 101, which is obtained after the application of the adhesion layer-forming composition 100, due to the impurities such as particles.

In the case where the adhesion layer-forming composition 100 is used in order to produce a circuit board used for a semiconductor device such as a semiconductor integrated circuit, the mixing of impurities containing metal atoms (metal impurities) in the adhesion layer-forming composition 100 is preferably avoided as much as possible. This is to prevent the operation of the circuit board from being hindered by the impurities such as metals. In this case, the concentration of the metal impurities contained in the adhesion layer-forming composition 100 is preferably 10 ppm or less, more preferably 100 ppb or less.

Thus, the adhesion layer-forming composition 100 is preferably prepared without being brought into contact with metal in the production process. Specifically, in the cases where the raw materials of the curable base material (A), the polymerization inhibitor (B), the solvent (C), and the crosslinker (D) and another component (E), which are added as needed, are weighed and mixed together and where the resulting mixture is stirred, it is preferable not to use metal weighing instruments, metal containers, or the like. In the purification process described above, further filtration is preferably performed with a metal-impurity-removing filter. Examples of the metal-impurity-removing filter that can be used include, but are not particularly limited to, cellulose filters, diatomaceous earth filters, and ion-exchange resin filters. These metal-impurity-removing filters are rinsed before use. Regarding a rinse method, rinsing with ultrapure water, rinsing with alcohol, and rinsing with the adhesion layer-forming composition 100 are preferably performed in this order.

Photocurable Composition

The photocurable composition 103 used together with the adhesion layer 101 formed from the adhesion layer-forming composition 100 according to the embodiment may usually contain a component (F), which is a polymerizable compound, and a component (G), which is a photopolymerization initiator.

Component (F): Polymerizable Compound

The component (F) is a polymerizable compound. The term “polymerizable compound” used in this specification refers to a compound that reacts with a polymerizing factor (for example, a radical) generated from the photopolymerization initiator (component (G)) to form a macromolecular compound (polymer) by a chain reaction (polymerization reaction). The component (F) may be composed of a single type of polymerizable compound or multiple types of polymerizable compounds. Examples of the polymerizable compound include radically polymerizable compounds. A radically polymerizable compound is preferably a compound having one or more acryloyl groups or methacryloyl groups, i.e., a (meth)acrylic compound.

Thus, the polymerizable compound serving as the component (F) preferably contains the (meth)acrylic compound. More preferably, the main component of the component (F) is the (meth)acrylic compound, most preferably a (meth)acrylic compound. The expression “the main component of the component (F) is the (meth)acrylic compound” indicates that 90% by weight or more of the component (F) is composed of the (meth)acrylic compound.

In the case where the radically polymerizable compound contains multiple types of compounds having one or more acryloyl groups or methacryloyl groups, a monofunctional (meth)acrylate monomer and a multifunctional (meth)acrylate monomer are preferably contained. This is because the combination of the monofunctional (meth)acrylate monomer and the multifunctional (meth)acrylate monomer provides a cured product having high strength.

Examples of the monofunctional (meth)acrylic compound having one acryloyl group or methacryloyl group include, but are not limited to, phenoxyethyl (meth)acrylate, phenoxy-2-methylethyl (meth)acrylate, phenoxyethoxyethyl (meth)acrylate, 3-phenoxy-2-hydroxypropyl (meth)acrylate, 2-phenylphenoxyethyl (meth)acrylate, 4-phenylphenoxyethyl (meth)acrylate, 3-(2-phenylphenyl)-2-hydroxypropyl (meth)acrylate, (meth)acrylate of EO-modified p-cumylphenol, 2-bromophenoxyethyl (meth)acrylate, 2,4-dibromophenoxyethyl (meth)acrylate, 2,4,6-tribromophenoxyethyl (meth)acrylate, EO-modified phenoxy (meth)acrylate, PO-modified phenoxy (meth)acrylate, polyoxyethylene nonylphenyl ether (meth)acrylate, isobornyl (meth)acrylate, 1-adamantyl (meth)acrylate, 2-methyl-2-adamantyl (meth)acrylate, 2-ethyl-2-adamantyl (meth)acrylate, bornyl (meth)acrylate, tricyclodecanyl (meth)acrylate, dicyclopentanyl (meth)acrylate, dicyclopentenyl (meth)acrylate, cyclohexyl (meth)acrylate, 4-butylcyclohexyl (meth)acrylate, acryloylmorpholine, 2-hydroxyethyl (meth)acrylate, 2-hydroxypropyl (meth)acrylate, 2-hydroxybutyl (meth)acrylate, methyl (meth)acrylate, ethyl (meth)acrylate, propyl (meth)acrylate, isopropyl (meth)acrylate, butyl (meth)acrylate, amyl (meth)acrylate, isobutyl (meth)acrylate, t-butyl (meth)acrylate, pentyl (meth)acrylate, isoamyl (meth)acrylate, hexyl (meth)acrylate, heptyl (meth)acrylate, octyl (meth)acrylate, isooctyl (meth)acrylate, 2-ethylhexyl (meth)acrylate, nonyl (meth)acrylate, decyl (meth)acrylate, isodecayl (meth)acrylate, undecyl (meth)acrylate, dodecyl (meth)acrylate, lauryl (meth)acrylate, stearyl (meth)acrylate, isostearyl (meth)acrylate, benzyl (meth)acrylate, 1-naphthylmethyl (meth)acrylate, 2-naphthylmethyl (meth)acrylate, tetrahydrofurfuryl (meth)acrylate, butoxyethyl (meth)acrylate, ethoxy diethylene glycol (meth)acrylate, poly(ethylene glycol) mono(meth)acrylate, poly(propylene glycol) mono(meth)acrylate, methoxy ethylene glycol (meth)acrylate, ethoxyethyl (meth)acrylate, methoxy poly(ethylene glycol) (meth)acrylate, methoxy poly(propylene glycol) (meth)acrylate, diacetone (meth)acrylamide, isobutoxymethyl (meth)acrylamide, N,N-dimethyl (meth)acrylamide, t-octyl (meth)acrylamide, dimethylaminoethyl (meth)acrylate, diethylaminoethyl (meth)acrylate, 7-amino-3,7-dimethyloctyl (meth)acrylate, N,N-diethyl (meth)acrylamide, and N,N-dimethylaminopropyl (meth)acrylamide.

Examples of commercially available products of the monofunctional (meth)acrylic compound include, but are not limited to, Aronix M101, M102, M110, Mill, M113, M117, M5700, TO-1317, M120, M150, and M156 (available from Toagosei Co., Ltd.), MEDOL10, MIBDOL10, CHDOL10, MMDOL30, MEDOL30, MIBDOL30, CHDOL30, LA, IBXA, 2-MTA, HPA, Viscoat #150, #155, #158, #190, #192, #193, #220, #2000, #2100, and #2150 (available from Osaka Organic Chemical Industry Ltd.), Light Acrylate BO-A, EC-A, DMP-A, THF-A, HOP-A, HOA-MPE, HOA-MPL, PO-A, P-200A, NP-4EA, NP-8EA, and Epoxy Ester M-600A (available from Kyoeisha Chemical Co., Ltd.), KAYARAD TC110S, R-564, and R-128H (available from Nippon Kayaku Co., Ltd.), NK Ester AMP-10G and AMP-20G (available from Shin-Nakamura Chemical Co., Ltd.), FA-511A, 512A, and 513A (available from Hitachi Chemical Co., Ltd.), PHE, CEA, PHE-2, PHE-4, BR-31, BR-31M, and BR-32 (available from Dai-ichi Kogyo Seiyaku Co., Ltd.), VP (available from BASF), and ACMO, DMAA, and DMAPAA (available from Kohjin Co., Ltd).

Examples of the multifunctional (meth)acrylic compound having two or more acryloyl groups or methacryloyl groups include, but are not limited to, trimethylolpropane di(meth)acrylate, trimethylolpropane tri(meth)acrylate, EO-modified trimethylolpropane tri(meth)acrylate, PO-modified trimethylolpropane tri(meth)acrylate, EO, PO-modified trimethylolpropane tri(meth)acrylate, dimethyloltricyclodecane diacrylate, pentaerythritol tri(meth)acrylate, pentaerythritol tetra(meth)acrylate, ethylene glycol di(meth)acrylate, tetraethylene glycol di(meth)acrylate, poly(ethylene glycol) di(meth)acrylate, poly(propylene glycol) di(meth)acrylate, 1,4-butanediol di(meth)acrylate, 1,6-hexanediol di(meth)acrylate, neopentyl glycol di(meth)acrylate, 1,3-adamantane dimethanol diacrylate, o-xylylene di(meth)acrylate, m-xylylene di(meth)acrylate, p-xylylene di(meth)acrylate, 1,9-nonanediol diacrylate, 1,10-decanediol diacrylate, tris(2-hydroxyethyl)isocyanurate tri(meth)acrylate, tris(acryloyloxy)isocyanurate, bis(hydroxymethyl)tricyclodecane di(meth)acrylate, dipentaerythritol penta(meth)acrylate, dipentaerythritol hexa(meth)acrylate, EO-modified 2,2-bis(4-((meth)acryloxy)phenyl)propane, PO-modified 2,2-bis(4-((meth)acryloxy)phenyl)propane, and EO, PO-modified 2,2-bis(4-((meth)acryloxy)phenyl)propane.

Examples of commercially available products of the multifunctional (meth)acrylic compound include, but are not limited to, Yupimer UV SA1002 and SA2007 (available from Mitsubishi Chemical Corporation), Viscoat #195, #230, #215, #260, #335HP, #295, #300, #360, #700, GPT, and 3PA (available from Osaka Organic Chemical Industry Ltd.), Light Acrylate 4EG-A, 9EG-A, NP-A, DCP-A, BP-4EA, BP-4PA, TMP-A, PE-3A, PE-4A, and DPE-6A (available from Kyoeisha Chemical Co., Ltd.), A-DCP, A-HD-N, A-NOD-N, and A-DOD-N (available from Shin-Nakamura Chemical Co., Ltd.), KAYARAD PET-30, TMPTA, R-604, DPHA, DPCA-20, -30, -60, -120, HX-620, D-310, and D-330 (available from Nippon Kayaku Co., Ltd.), Aronix M208, M210, M215, M220, M240, M305, M309, M310, M315, M325, and M400 (available from Toagosei Co., Ltd.), and Ripoxy VR-77, VR-60, and VR-90 (available from Showa Denko K.K).

The term “(meth)acrylate” used in the foregoing compounds refers to an acrylate or a methacrylate having an alcohol residue equivalent to that thereof. The term “(meth)acryloyl group” refers to an acryloyl group or a methacryloyl group having an alcohol residue equivalent to that thereof. The term “EO” refers to ethylene oxide, and an “EO-modified compound A” refers to a compound in which a (meth)acrylic acid residue and an alcohol residue of the compound A are bonded to each other with a block structure formed of the ethylene oxide group provided therebetween. The term “PO” refers to propylene oxide, and a “PO-modified compound B” refers to a compound in which a (meth)acrylic acid residue and an alcohol residue of the compound B are bonded to each other with a block structure formed of the propylene oxide group provided therebetween.

Component (G): Photopolymerization Initiator

The component (G) is a photopolymerization initiator. The photopolymerization initiator used in this specification is a compound that senses light having a predetermined wavelength to generate a polymerizing factor (radical). Specifically, the photopolymerization initiator is a polymerization initiator (radical generator) that generates a radical in response to light (for example, infrared light, visible light, ultraviolet light, far-ultraviolet light, X-rays, charged particle radiation such as an electron beam, or radiation). More specifically, the photopolymerization initiator is a polymerization initiator that generates a radical in response to light having a wavelength of, for example, 150 nm or more and 400 nm or less. The component (G) may be formed of a single type of photopolymerization initiator or multiple types of photopolymerization initiators.

Examples of the radical generator include optionally substituted 2,4,5-triarylimidazole dimers such as 2-(o-chlorophenyl)-4,5-diphenylimidazole dimer, 2-(o-chlorophenyl)-4,5-di(methoxyphenyl)imidazole dimer, 2-(o-fluorophenyl)-4,5-diphenylimidazole dimer, and 2-(o- or p-methoxyphenyl)-4,5-diphenylimidazole dimer. Examples of the radical generator also include benzophenone and benzophenone derivatives such as N,N′-tetramethyl-4,4′-diaminobenzophenone (Michler's ketone), N,N′-tetraethyl-4,4′-diaminobenzophenone, 4-methoxy-4′-dimethylaminobenzophenone, 4-chlorobenzophenone, 4,4′-dimethoxybenzophenone, and 4,4′-diaminobenzophenone. Examples of the radical generator also include α-aminoaromatic ketone derivatives such as 2-benzyl-2-dimethylamino-1-(4-morpholinophenyl)-butanone-1 and 2-methyl-1-[4-(methylthio)phenyl]-2-morpholino-propan-1-one. Examples of the radical generator also include quinones such as 2-ethylanthraquinone, phenanthrene quinone, 2-t-butylanthraquinone, octamethylanthraquinone, 1,2-benzanthraquinone, 2,3-benzanthraquinone, 2-phenylanthraquinone, 2,3-diphenylanthraquinone, 1-chloroanthraquinone, 2-methylanthraquinone, 1,4-naphthoquinone, 9,10-phenanthraquinone, 2-methyl-1,4-naphthoquinone, and 2,3-dimethylanthraquinone. Benzoin ether derivatives such as benzoin methyl ether, benzoin ethyl ether, and benzoin phenyl ether may also be exemplified. Examples of the radical generator also include benzoin and benzoin derivatives such as methylbenzoin, ethylbenzoin, and propylbenzoin. Examples of the radical generator also include benzil derivatives such as benzil dimethylketal. Examples of the radical generator also include acridine derivatives such as 9-phenylacridine and 1,7-bis(9,9′-acridinyl)heptane. N-Phenylglycine and N-phenylglycine derivatives may also be exemplified. Examples of the radical generator also include acetophenone and acetophenone derivatives such as 3-methylacetophenone, acetophenone benzyl ketal, 1-hydroxycyclohexyl phenyl ketone, and 2,2-dimethoxy-2-phenylacetophenone; and thioxanthone and thioxanthone derivatives such as diethylthioxanthone, 2-isopropylthioxanthone, and 2-chlorothioxanthone. Examples of the radical generator also include acylphosphine oxide derivatives such as 2,4,6-trimethylbenzoyldiphenylphosphine oxide, bis(2,4,6-trimethylbenzoyl)phenylphosphine oxide, and bis-(2,6-dimethoxybenzoyl)-2,4,4-trimethylpentylphosphine oxide. Examples of the radical generator also include oxime ester derivatives such as 1,2-octanedione, 1-[4-(phenylthio)-, 2-(O-benzoyloxime)] and ethanone, 1-[9-ethyl-6-(2-methylbenzoyl)-9H-carbazol-3-yl]-, 1-(O-acetyloxime). Examples of the radical generator also include xanthone, fluorenone, benzaldehyde, fluorene, anthraquinone, triphenylamine, carbazole, 1-(4-isopropylphenyl)-2-hydroxy-2-methylpropan-1-one, and 2-hydroxy-2-methyl-1-phenylpropan-1-one. The radical generator is not limited to one of the foregoing compounds and may be another compound.

Examples of commercially available products of the radical generator that can be used include, but are not limited to, Irgacure 184, 369, 651, 500, 819, 907, 784, 2959, CGI-1700, -1750, -1850, CG24-61, Darocur 1116, 1173, Lucirin TPO, LR8893, and LR8970 (available from BASF), and Ebecryl P36 (available from UCB).

The percentage of the component (G) incorporated in the photocurable composition 103 is preferably 0.01% by weight or more and 10% by weight or less, more preferably 0.1% by weight or more and 7% by weight or less based on the total amount of the component (F).

In the case where the percentage of the component (G) incorporated in the photocurable composition 103 is 0.01% by weight or more based on the total amount of the component (F), the curing rate of the photocurable composition 103 can be increased to enhance the reaction efficiency. In the case where the percentage of the component (G) incorporated is 10.0% by weight or less based on the total amount of the component (F), the degradation of the mechanical strength of the cured product 109 can be reduced.

Another Additive Component (H)

The photocurable composition 103 may further contain an additive component (H) in addition to the components (F) and (G), depending on various purposes. Examples of the additive component (H) include sensitizers, hydrogen donors, internal mold release agents, surfactants, antioxidants, volatile solvents, polymer components, and polymerization initiators other than the component (G).

A sensitizer is a compound optionally added to promote a polymerization reaction and improve the reaction conversion. Examples of the sensitizers include sensitizing dyes. The sensitizers may be used alone or in combination of two or more as a mixture.

A sensitizing dye is a compound that is excited by absorbing light having a specific wavelength and that interacts with the component (G). The term “interaction” used here refers to energy transfer or electron transfer from a sensitizing dye in an excited state to the component (G). Specific examples of the sensitizing dye include, but are not limited to, anthraquinone derivatives, anthraquinone derivatives, pyrene derivatives, perylene derivatives, carbazole derivatives, benzophenone derivatives, thioxanthone derivatives, xanthone derivatives, coumarin derivatives, phenothiazine derivatives, camphorquinone derivatives, acridine-based dyes, thiopyrylium salt-based dyes, merocyanine-based dyes, quinoline-based dyes, styrylquinoline-based dyes, ketocoumarin-based dyes, thioxanthene-based dyes, xanthene-based dyes, oxonol-based dyes, cyanine-based dyes, rhodamine-based dyes, and pyrylium salt-based dyes.

A hydrogen donor is a compound that reacts with an initiator radical generated from the component (G) or that reacts with a radical at a propagating end to form a more reactive radical. The hydrogen donor is preferably added when the component (G) is a photo-radical generator. Specific examples of the hydrogen donor include, but are not limited to, amine compounds such as n-butylamine, di-n-butylamine, tri-n-butylphosphine, allylthiourea, s-benzylisothiuronium-p-toluene sulfinate, triethylamine, diethylaminoethyl methacrylate, triethylenetetramine, 4,4′-bis(dialkylamino)benzophenone, ethyl N,N-dimethylaminobenzoate, isoamyl N,N-dimethylaminobenzoate, pentyl-4-dimethylaminobenzoate, triethanolamine, and N-phenylglycine; and mercapto compounds such as 2-mercapto-N-phenylbenzimidazol and mercaptopropionates. The hydrogen donors may be used alone or in combination of two or more as a mixture. The hydrogen donor may function as a sensitizer.

In the case where the photocurable composition 103 contains the sensitizer and the hydrogen donor as another additive component (H), each of the sensitizer content and the hydrogen donor content is preferably 0.1% by weight or more and 20% by weight or less, more preferably 0.1% by weight or more and 5.0% by weight or less, even more preferably 0.2% by weight or more and 2.0% by weight or less based on the total amount of the component (F). When the sensitizer content is 0.1% by weight or more based on the total amount of the component (F), the effect of promoting the polymerization can be provided more effectively. When the sensitizer content or the hydrogen donor content is 5.0% by weight or less, the molecular weight of a macromolecular compound contained in a cured product to be formed can be sufficiently increased. Furthermore, insufficient dissolution of the sensitizer or the hydrogen donor in the photocurable composition 103 and a decrease in the storage stability of the photocurable composition 103 can be reduced.

To reduce the interface bonding force between the mold 104 and the cured product 109 obtained by curing the photocurable composition 103, in other words, to reduce a separating force (mold release force) in the separation step, an internal mold release agent can be added to the photocurable composition 103. The term “internal” of the internal mold release agent used in this specification indicates that the internal mold release agent is added to the photocurable composition 103 in advance before the placement step of placing the photocurable composition 103. A single type of internal mold release agent may be used alone. Alternatively, two or more types of internal mold release agent may be used in combination as a mixture.

Examples of the internal mold release agent that can be used include surfactants such as silicone-based surfactants, fluorine-based surfactants, and hydrocarbon-based surfactants. In the embodiment, the internal mold release agent is not polymerizable.

Such a fluorine-based surfactant may contain an adduct such as a poly(alkylene oxide) (for example, poly(ethylene oxide) or poly(propylene oxide)) adduct of an alcohol having a perfluoroalkyl group or a poly(alkylene oxide) (for example, poly(ethylene oxide) or poly(propylene oxide)) adduct of perfluoropolyether. The fluorine-based surfactant may have a hydroxy group, an alkoxy group, an alkyl group, an amino group, or a thiol group as a portion of the molecular structure (for example, an end group).

As the fluorine-based surfactant, a commercially available product may be used. Examples of the commercially available product include, but are not limited to, Megaface F-444, TF-2066, TF-2067, and TF-2068 (available from DIC Corporation), Fluorad FC-430 and FC-431 (available from Sumitomo 3M Limited), Surflon S-382 (available from AGC Inc.), EFTOP EF-122A, 122B, 122C, EF-121, EF-126, EF-127, and MF-100 (available from Tohchem Products Co., Ltd.), PF-636, PF-6320, PF-656, and PF-6520 (available from OMNOVA Solutions), Unidyne DS-401, DS-403, and DS-451 (available from Daikin Industries, Ltd.), Ftergent 250, 251, 222F, and 208G (available from Neos Company Limited).

The internal mold release agent may contain, for example, a hydrocarbon-based surfactant. The hydrocarbon-based surfactant may contain, for example, a poly(alkylene oxide) adduct of an alkyl alcohol in which an alkylene oxide having a 2 to 4 carbon atoms is added to an alkyl alcohol having 1 to 50 carbon atoms.

Examples of the poly(alkylene oxide) adduct of an alkyl alcohol include an ethylene oxide adduct of methyl alcohol, an ethylene oxide adduct of decyl alcohol, an ethylene oxide adduct of lauryl alcohol, an ethylene oxide adduct of cetyl alcohol, an ethylene oxide adduct of stearyl alcohol, and an ethylene oxide/propylene oxide adduct of stearyl alcohol. The end group of the poly(alkylene oxide) adduct of an alkyl alcohol is not limited to a hydroxy group, which can be formed by merely adding a poly(alkylene oxide) to an alkyl alcohol. The hydroxy group may be converted into another substituent, for example, a polar functional group such as a carboxy group, an amino group, a pyridyl group, a thiol group, or a silanol group, or a hydrophobic functional group such as an alkyl group or an alkoxy group.

As the poly(alkylene oxide) adduct of an alkyl alcohol, a commercially available product may be used. Examples of the commercially available product include, but are not limited to, polyoxyethylene methyl ether (an ethylene oxide adduct of methyl alcohol) (e.g., BLAUNON MP-400, MP-550, and MP-1000) available from Aoki Oil Industrial Co., Ltd.; polyoxyethylene decyl ether (an ethylene oxide adduct of decyl alcohol) (e.g., FINESURF D-1303, D-1305, D-1307, and D-1310) available from Aoki Oil Industrial Co., Ltd.; polyoxyethylene lauryl ether (an ethylene oxide adduct of lauryl alcohol) (e.g., BLAUNON EL-1505) available from Aoki Oil Industrial Co., Ltd.; polyoxyethylene cetyl ether (an ethylene oxide adduct of cetyl alcohol) (e.g., BLAUNON CH-305 and CH-310) available from Aoki Oil Industrial Co., Ltd.; polyoxyethylene stearyl ether (an ethylene oxide adduct of stearyl alcohol) (e.g., BLAUNON SR-705, SR-707, SR-715, SR-720, SR-730, and SR-750) available from Aoki Oil Industrial Co., Ltd.; polyoxyethylene polyoxypropylene stearyl ether prepared by random polymerization (e.g., BLAUNON SA-50/50 1000R and SA-30/70 2000R) available from Aoki Oil Industrial Co., Ltd.; polyoxyethylene methyl ether (e.g., Pluriol A760E) available from BASF; and polyoxyethylene alkyl ether (Emulgen series) available from Kao Corporation.

Among these hydrocarbon-based surfactants, the internal mold release agent is preferably a poly(alkylene oxide) adduct of an alkyl alcohol, more preferably a poly(alkylene oxide) adduct of a long-chain alkyl alcohol.

In the case where the photocurable composition 103 contains the internal mold release agent as another additive component (H), the internal mold release agent content is preferably, for example, 0.001% by weight or more and 10% by weight or less, more preferably 0.01% by weight or more and 7% by weight or less, even more preferably 0.05% by weight or more and 5% by weight or less based on the total amount of the component (F). The at least use of an internal mold release agent content of 0.001% by weight or more and 10% by weight or less is effective in reducing the mold release force and provides good filling properties.

The photocurable composition 103 may contain a volatile solvent as another additive component (H). Preferably, the photocurable composition 103 is substantially free from a volatile solvent. The phrase “substantially free from a volatile solvent” indicates that a volatile solvent other than an unintentionally contained volatile solvent, such as impurities, is not contained. For example, the photocurable composition 103 preferably has a volatile solvent content of 3% by weight or less, more preferably 1% by weight or less based on the total of the photocurable composition 103. The term “volatile solvent” used here refers to a volatile solvent commonly used for photocurable composition 103 and photoresists. In other words, any type of volatile solvent may be used as long as it dissolves the compounds constituting the photocurable composition 103, uniformly disperses the compounds, and does not react with the compounds.

Temperature During Preparation of Photocurable Composition

When the photocurable composition 103 according to the embodiment is prepared, at least the component (F) and the component (G) are mixed and dissolved under predetermined temperature conditions, specifically, in the range of 0° C. or higher and 100° C. or lower. The same applies to the case of containing another additive component (H).

Viscosity of Photocurable Composition

The mixture of the components, excluding the volatile solvent, in the photocurable composition 103 according to the embodiment preferably has a viscosity at 23° C. of 1 mPa·s or more and 100 mPa·s or less, more preferably 1 mPa·s or more and 50 mPa·s or less, even more preferably 1 mPa·s or more and 20 mPa·s or less.

In the case where the photocurable composition 103 has a viscosity of 100 mPa·s or less, it takes less time to fill the photocurable composition 103 into the recessed portion of the fine pattern of the mold when the photocurable composition 103 is brought into contact with the mold 104. Additionally, pattern defects due to the failure of filling are less likely to occur.

At a viscosity of 1 mPa·s or more, when the photocurable composition 103 is applied to the base 102, non-uniform application is not easily occur. Additionally, when the photocurable composition 103 is brought into contact with the mold 104, the photocurable composition 103 does not easily flow out of an end portion of the mold 104.

Surface Tension of Photocurable Composition

Regarding the surface tension of the photocurable composition 103 according to the embodiment, the mixture of the components excluding the solvent preferably has a surface tension at 23° C. of 5 mN/m or more and 70 mN/m or less, more preferably 7 mN/m or more and 35 mN/m or less, even more preferably 10 mN/m or more and 32 mN/m or less. At a surface tension of 5 mN/m or more, it takes less time to fill the photocurable composition 103 into the recessed portion of the fine pattern of the mold 104 when the photocurable composition 103 is brought into contact with the mold 104.

At a surface tension of 70 mN/m or less, the cured product 109 obtained by photocuring the photocurable composition 103 is a cured film having a smooth surface.

Evaluation of Polymerization Inhibition Effect

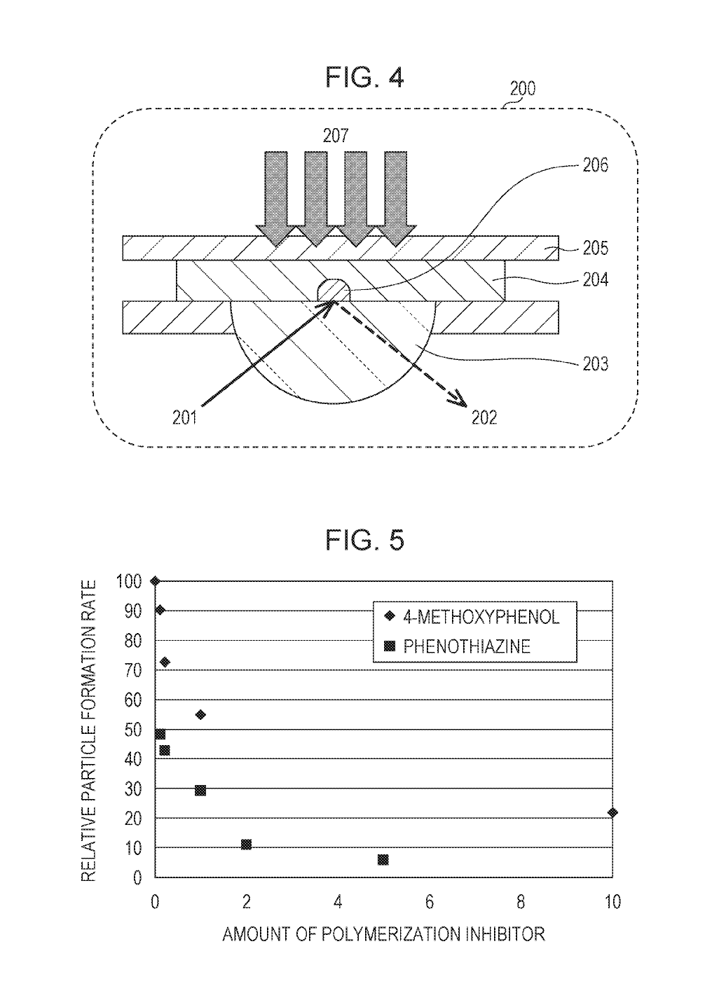

A polymerization inhibition effect used in the present invention can be evaluated by a polymerization conversion measured with, for example, an attenuated total reflection infrared spectrometer 200 including a light irradiation portion as illustrated in FIG. 4. The polymerization conversion used here can be defined as the percentage of disappearance of the polymerizable functional group of the curable base material. The percentage is synonymous with the percentage of the polymerizable functional group that has been polymerized.

In the attenuated total reflection infrared spectrometer 200 illustrated in FIG. 4, a curable composition 204 is disposed between a diamond ATR crystal 203 and quartz glass 205 included in the attenuated total reflection infrared spectrometer 200 illustrated in FIG. 4. The curable composition 204 is cured by irradiation with irradiating light 207 toward the curable composition 204 through the quartz glass 205. The diamond ATR crystal 203 is irradiated with infrared light 201. An evanescent wave 206 generated in the range of several micrometers on the diamond ATR crystal 203 is detected by a detector 202. Several or more and several tens or less attenuated total reflection infrared spectra of the curable composition 204 are acquired per second. Thus, the infrared spectra of the curable composition during photocuring can be acquired in real time. The polymerization conversion (%) of the curable composition at a freely-selected exposure can be calculated by formula (1) below.

[Polymerization conversion (%)]=100×(1−P2/P1) (1)

(where in formula (1), P1 represents the peak intensity (initial intensity) of a peak originating from the polymerizable functional group of the curable base material immediately after the initiation of the light irradiation, and P2 represents the peak intensity (initial intensity) of the peak originating from the polymerizable functional group of the curable base material after the exposure for a freely-selected time).

In this specification, a minimum exposure (mJ/cm²) when the polymerization conversion is more than 50% at an illuminance of 1 mW/cm² is defined as a half decay exposure (mJ/cm²) and used as an index of the polymerization rate of the curable composition. A larger value of the half decay exposure indicates slower photopolymerization and a higher polymerization inhibition effect. In addition to assuming that gel particles spontaneously formed in an adhesion layer solution are a radical polymerization product, it is assumed that the gel particle formation rate is proportional to the thermal radical polymerization rate of the curable base material and also proportional to the photo-radical polymerization rate of the curable base material. In this assumption, the polymerization inhibition effect of the polymerization inhibitor can be evaluated by a change in photopolymerization rate. Specifically, the polymerization inhibition effect can be quantitatively evaluated by adding the polymerization inhibitor to a photo-radical polymerizable composition and measuring the half decay exposure.

Impurity Mixed in Photocurable Composition

Impurities in the photocurable composition 103 according to the embodiment are preferably minimized, similarly to the adhesion layer-forming composition 100. Thus, the photocurable composition 103 is preferably obtained through a purification process, similarly to the adhesion layer-forming composition 100. A preferred example of the purification process is filtration with a filter.

In the case where the filtration with a filter is performed, specifically, the component (F), the component (G), and the additive component (H), which is added as needed, are mixed together, the mixture is preferably filtered through a filter having a pore size of, for example, 0.001 μm or more and 5.0 μm or less. In the case where the filtration with the filter is performed, the filtration is more preferably performed in multiple stages or repeated many times. The resulting filtrate may be filtered again. The filtration may be performed with multiple filters having different pore sizes. Examples of the filter used for the filtration include, but are not particularly limited to, polyethylene resin filters, polypropylene resin filters, fluororesin filters, and nylon resin filters.

Impurities such as particles mixed in the photocurable composition 103 can be removed through the purification process. This makes it possible to prevent the occurrence of pattern defects resulting from unintentional irregularities on the cured product 109, which is obtained after the photocuring of the photocurable composition 103, due to the impurities such as particles.

In the case where the photocurable composition 103 is used in order to produce a circuit board used for a semiconductor device such as a semiconductor integrated circuit, the mixing of impurities containing metal atoms (metal impurities) in the photocurable composition 103 is preferably avoided as much as possible. This is to prevent the operation of the circuit board from being hindered by the impurities such as metals, similarly to impurities mixed in the adhesion layer-forming composition 100. In this case, the concentration of the metal impurities contained in the photocurable composition 103 is preferably 10 ppm or less, more preferably 100 ppb or less.

Thus, the photocurable composition 103 is preferably prepared without being brought into contact with metal in the production process. Specifically, in the cases where the raw materials of the component (F), the component (G), and the additive component (H) are weighed and mixed together and where the resulting mixture is stirred, it is preferable not to use metal weighing instruments, metal containers, or the like. In the purification process described above, further filtration is preferably performed with a metal-impurity-removing filter. Examples of the metal-impurity-removing filter that can be used include, but are not particularly limited to, cellulose filters, diatomaceous earth filters, and ion-exchange resin filters. These metal-impurity-removing filters are rinsed before use. Regarding a rinse method, rinsing with ultrapure water, rinsing with alcohol, and rinsing with the photocurable composition 103 are preferably performed in this order.

Method for Forming Pattern (Method for Producing Article)

More specific example of a method for forming a pattern or a method for producing an article according to an embodiment will be described with reference again to FIG. 3. According to the method for forming a pattern, a pattern having a size of, for example, 1 nm or more and 100 mm or less can be formed with a cured product.

Steps will be described below by specific examples.

Adhesion Layer Formation Step

FIGS. 3A and 3B schematically illustrate the adhesion layer formation step. In the adhesion layer formation step, the adhesion layer 101 mainly containing a macromolecular compound (polymer) is formed on the base 102 with the adhesion layer-forming composition 100.

The base 102 is a substrate or a support. Depending on various purposes, any base may be selected. Examples of the base that can be used include substrates for semiconductor devices, such as silicon wafers, aluminum, titanium-tungsten alloys, aluminum-silicon alloys, aluminum-copper-silicon alloys, silicon oxide, and silicon nitride, quartz, glass, optical film, ceramic materials, deposited films, magnetic films, reflecting films, bases of metals such as Ni, Cu, Cr, and Fe, polymer bases of paper, polyester films, polycarbonate films, polyimide films, TFT array bases, electrode plates of PDPs, plastic bases, electrically conductive bases of ITO and metals, and insulating bases. However, in the case where the base 102 is processed by, for example, etching in the processing step illustrated in FIG. 3H, a substrate for a semiconductor device, such as a silicon wafer, is preferably used. The base 102 may include a single type or multiple types of films composed of, for example, spin-on glass, an organic material, a metal, an oxide, or a nitride disposed on the substrate. In a semiconductor manufacturing process, commonly, the adhesion layer 101 is formed on the base 102.

As the base 102, in particular, a base having hydroxy groups (OH groups) such as silanol groups (SiOH groups) on a surface thereof is preferably used. Examples of the base include silicon wafers, quartz, and glass. The use of the base having hydroxy groups on the surface will easily form chemical bonds between the hydroxy groups on the surface of the base 102 and the curable base material (A) in the heating step.

In the step illustrated in FIG. 3A, the adhesion layer-forming composition 100 is applied (disposed) to the base 102. For the application of the adhesion layer-forming composition 100, for example, an inkjet method, a dip-coating method, an air-knife coating method, a curtain-coating method, a wire-bar coating method, a gravure-coating method, an extrusion-coating method, a spin-coating method, or a slit-scanning method may be employed. Among these methods, the spin-coating method is particularly preferred in view of coating properties, in particular, thickness uniformity.

After the adhesion layer-forming composition 100 is applied to the base 102, the heating step illustrated in FIG. 3B is performed in order to evaporate the organic solvent (C) while the polymerization inhibitor (B) is volatilized. The base 102 reacts with the curable base material (A) to form a bond in the heating step, simultaneously with the volatilization of the polymerization inhibitor (B) and the evaporation of the organic solvent (C). The crosslinker (D) allows the crosslinking reaction of the curable base material (A) to proceed. In the heating step, the polymerization inhibitor (B) and the crosslinker (D) react with each other to eliminate the polymerization inhibition effect of the polymerization inhibitor. For example, when the polymerization inhibitor (B) and the crosslinker (D) react with each other in the heating step, the concentration of the polymerization inhibitor (B) in the adhesion layer 101 is less than 0.1 parts by weight.

A preferable temperature in the heating step may be appropriately selected, depending on the reactivity of the curable base material (A) with the base 102, the boiling points of the curable base material (A), the polymerization inhibitor (B), and the organic solvent (C), and the reactivity of the polymerization inhibitor (B) with the crosslinker (D). The temperature in the heating step is, for example, 70° C. or higher and 280° C. or lower, preferably 100° C. or higher and 265° C. or lower, more preferably 140° C. or higher and 250° C. or lower. The evaporation of the organic solvent (C), the volatilization of the polymerization inhibitor (B), the reaction between the base 102 and the curable base material (A), and the reaction between the polymerization inhibitor (B) and the crosslinker (D) may be performed at different temperatures.

The thickness of the adhesion layer 101 formed through the heating step varies, depending on applications, and is, for example, 0.1 nm or more and 100 nm or less, preferably 0.5 nm or more and 60 nm or less, more preferably 1 nm or more and 10 nm or less.

In the case where the adhesion layer-forming composition 100 is applied to the base 102 to form the adhesion layer 101, an adhesion layer serving as a second layer may be formed on the adhesion layer 101 serving as a first layer with the adhesion layer-forming composition 100. This method can be what is called multiple coatings. The adhesion layer 101 preferably has a surface as smooth as possible and preferably has a surface roughness of 1 nm or less.

Placement Step

FIG. 3C schematically illustrates the placement step. In the placement step, the photocurable composition 103 is placed (applied) on the adhesion layer 101 on the base 102. For the placement of the photocurable composition 103, for example, an inkjet method, a dip-coating method, an air-knife coating method, a curtain-coating method, a wire-bar coating method, a gravure-coating method, an extrusion-coating method, a spin-coating method, or a slit-scanning method may be employed. Among these methods, the spin-coating method is particularly preferred in a photo-imprint method. The thickness of the photocurable composition 103 varies, depending on applications, and is for example, 0.01 μm or more and 100.0 μm or less.

Contact Step

FIG. 3D schematically illustrates the contact step. In the contact step, the pattern region of the mold 104 is brought into contact with the photocurable composition 103 placed on the base 102 with the adhesion layer 101 provided therebetween in the placement step. Thereby, the photocurable composition 103 is filled into the recessed portion of the protruding portion and the recessed portion constituting the pattern in the pattern region of the mold 104, and the photocurable composition 103 spreads between the adhesion layer 101 and the pattern region of the mold 104 to form a coating film 105.

As the mold 104, a mold composed of a material that transmits light can be used in consideration of the subsequent curing step. As the material constituting the mold 104, specifically, glass or quartz is preferred. The material constituting the mold 104 may be an optically transparent resin such as PMMA or a polycarbonate resin, a transparent evaporated metal film, a flexible film composed of polydimethylsiloxane, a photocured film, or a metal film. However, in the case where an optically transparent resin is used as a material constituting the mold 104, it is necessary to select a resin insoluble in a component contained in the photocurable composition 103. The material constituting the mold 104 is particularly preferably quartz because of a low thermal expansion coefficient and a low pattern distortion.

The fine pattern on a surface of the mold 104 preferably has a pattern height of 4 nm or more and 200 nm or less and an aspect ratio of 1 or more and 10 or less.

To improve the releasability of the photocurable composition 103 from the surface of the mold 104, the mold 104 may be subjected to surface treatment before the contact step of bringing the photocurable composition 103 into contact with the mold 104. An example of a surface treatment method is a method in which a mold release agent is applied to the surface of the mold 104 to form a mold release agent layer. Examples of the mold release agent include silicone-based mold release agents, fluorine-based mold release agents, hydrocarbon-based mold release agents, polyethylene-based mold release agents, polypropylene-based mold release agents, paraffin-based mold release agents, montan-based mold release agents, and carnauba-based mold release agents. For example, a commercially available application-type mold release agent such as Optool DSX available from Daikin Industries, Ltd., may also be appropriately used. These mold release agents may be used separately or in combination of two or more. Among these agents, the fluorine-based and hydrocarbon-based mold release agents are particularly preferred.

In the contact step, a pressure (mold pressure) applied to the photocurable composition 103 when the mold 104 is brought into contact with the photocurable composition 103 is not particularly limited. The pressure is usually 0 MPa or more and 100 MPa or less, preferably 0 MPa or more and 50 MPa or less, more preferably 0 MPa or more and 30 MPa or less, even more preferably 0 MPa or more and 20 MPa or less.

The length of time that the mold 104 is brought into contact with the photocurable composition 103 in the contact step is not particularly limited. The length of time is usually 0.1 seconds or more and 600 seconds or less, preferably 0.1 seconds or more and 300 seconds or less, more preferably 0.1 seconds or more and 180 seconds or less, particularly preferably 0.1 seconds or more and 120 seconds or less.

The contact step may be performed in an air atmosphere, a reduced-pressure atmosphere, or an inert gas atmosphere. To prevent the effects of oxygen and water on a curing reaction, the reduced-pressure atmosphere or an inter gas atmosphere is preferred. In the case of performing the contact step in the inert gas atmosphere, examples of an inert gas that can be used include nitrogen, carbon dioxide, helium, argon, various chlorofluorocarbon gases, and gas mixture thereof. In the case of performing the contact step in a specific gas atmosphere including the air atmosphere, the pressure is preferably 0.0001 atm or more and 10 atm or less.

The contact step may be performed in an atmosphere containing a condensable gas (hereinafter, referred to as a “condensable gas atmosphere”). The term “condensable gas” used in this specification refers to a gas that is condensed and liquefied by a capillary pressure generated by pressure during charging. Specifically, the condensable gas is condensed and liquefied when the gas in the atmosphere is charged into the recessed portion of the pattern formed on the mold 104 and a gap between the mold 104 and the base 102 or between the mold 104 and the adhesion layer 101 together with the coating film 105. The condensable gas is present in the form of gas in the atmosphere before the photocurable composition 103 is brought into contact with the mold 104 in the contact step. When the contact step is performed in the condensable gas atmosphere, the gas charged into the recessed portion of the pattern of the mold 104 is liquefied to allow bubbles to disappear, thus improving the filling properties. The condensable gas may be dissolved in the photocurable composition 103.

The boiling point of the condensable gas is not limited as long as it is equal to or lower than the ambient temperature in the contact step, and is preferably −10° C. to 23° C., more preferably 10° C. to 23° C. In this range, the filling properties are further improved. The vapor pressure of the condensable gas at the ambient temperature in the contact step is not limited as long as it is equal to lower than the pressure applied to the mold 104 in the contact step, and is preferably 0.1 to 0.4 MPa. In this range, the filling properties are further improved. At a vapor pressure of more than 0.4 MPa at the ambient temperature, the effect of allowing bubbles to disappear is likely to fail to be sufficiently provided. At a vapor pressure of less than 0.1 MPa, a reduction in pressure is required, thus possibly leading to an imprint apparatus having a complex structure. The ambient temperature in the contact step is preferably, but not necessarily, 20° C. to 25° C.

Specific examples of the condensable gas include, but are not limited to, Freons, for example, chlorofluorocarbons (CFCs) such as trichlorofluoromethane, fluorocarbons (FCs), hydrochlorofluorocarbons (HCFCs), hydrofluorocarbons (HFCs) such as 1,1,1,3,3-pentafluoropropane (CHF₂CH₂CF₃, HFC-245fa, PFP), and hydrofluoroether (HFEs) such as pentafluoroethyl methyl ether (CF₃CF₂OCH₃, HFE-245mc).

Among these, 1,1,1,3,3-pentafluoropropane (vapor pressure at 23° C.: 0.14 MPa, boiling point: 15° C.), trichlorofluoromethane (vapor pressure at 23° C.: 0.1056 MPa, boiling point: 24° C.), and pentafluoroethyl methyl ether are preferred. These have good filling properties in the contact step at an ambient temperature of 20° C. to 25° C. Furthermore, from the viewpoint of achieving good safety, 1,1,1,3,3-pentafluoropropane is particularly preferred.

These condensable gases may be used separately or in combination of two or more as a mixture. The condensable gas may be used in the form of a gas mixture in which the condensable gas is mixed with a non-condensable gas such as air, nitrogen, carbon dioxide, helium, or argon. As the non-condensable gas mixed with the condensable gas, helium is preferred in view of the filling properties. Helium can penetrate the mold 104. Thus, when the gases (the condensable gas and helium) in the atmosphere are filled into the recessed portion of the pattern of the mold 104 together with the coating film 105 in the contact step, the condensable gas liquefies, and helium penetrates the mold 104. Thus, the use of helium as the non-condensable gas results in good filling properties.

Alignment Step

The base 102 can be aligned with the mold 104 using marks of the mold 104 and the marks 107 of the base 102 before and/or during the contact step. However, in the case where high accuracy is not required, the base 102 may be aligned with the mold 104 on the basis of the relative positions of the base 102 and the mold 104 obtained in advance by measurement.

Curing Step

FIG. 3E schematically illustrates the curing step. In the curing step, the photocurable composition 103 (coating film 105) is irradiated with light 108 through the mold 104 while the photocurable composition 103 (coating film 105) is in contact with the pattern region of the mold 104. Thereby, the pattern of the cured product 109 obtained by curing the photocurable composition 103 (coating film 105) is formed.

The light 108 with which the photocurable composition 103 (coating film 105) is irradiated is selected, depending on a wavelength to which the photocurable composition 103 is sensitive. Specifically, the light 108 may be ultraviolet light having a wavelength of, for example, 150 nm or more and 400 nm or less. The light 108 may be, for example, X-rays or an electron beam.

Typically, the light 108 is ultraviolet light. This is because commercially available curing aids (photopolymerization initiators) are often formed of compounds sensitive to ultraviolet light. Examples of an ultraviolet light source that can be used include high-pressure mercury lamps, ultrahigh-pressure mercury lamps, low-pressure mercury lamps, Deep-UV lamps, carbon-arc lamps, chemical lamps, metal-halide lamps, xenon lamps, KrF excimer lasers, ArF excimer lasers, and F₂ excimer lasers. Among these, ultrahigh-pressure mercury lamps are particularly preferred. The number of light sources used may be one or two or more. The coating film 105 filled into the pattern of the mold 104 may be partially or entirely irradiated with light. The light irradiation may be intermittently performed multiple times or may be continuously performed. A partial region A may be irradiated with the light 108 in a first irradiation step, and then a region B different from the partial region A may be irradiated with the light 108 in a second irradiation step. The photocurable composition 103 is preferably exposed in an amount of 90 mJ/cm² or less, more preferably 30 mJ/cm² or less.

Separation Step

FIG. 3F schematically illustrates the separation step (release step). In the separation step, the cured product 109 is separated from the mold 104. The pattern of the mold 104 is transferred to the cured product 109.

In the case where the contact step is performed in the condensable gas atmosphere, the condensable gas is evaporated by virtue of a reduction in the pressure of the contact interface between the cured product 109 and the mold 104 when the cured product 109 is separated from the mold 104 in the separation step. This can reduce a separating force (releasing force), which is a force required to separate the cured product 109 from the mold 104.

A method for separating the cured product 109 from the mold 104 and conditions are not limited to particular method and conditions. For example, the mold 104 may be moved away from the base 102 with the base 102 fixed. The base 102 may be moved away from the mold 104 with the mold 104 fixed. Both may be moved in opposite directions.

It is possible to obtain a structure (article) in which the cured product 109 is disposed on the base 102 with the adhesion layer 101 provided therebetween through the foregoing steps. The structure can be used, for example, as the whole or part of an optical component such as a Fresnel lens or a diffraction grating.

Among the adhesion layer formation step, the placement step, the contact step, the curing step, and the separation step, a process at least including the contact step, the curing step, and the separation step can be performed individually for multiple shot regions of the base 102. The adhesion layer formation step and the placement step may be performed collectively or individually for the multiple shot regions of the base 102. The adhesion layer formation step may be performed collectively for the multiple shot regions of the base 102, and the placement step may be performed individually for the multiple shot regions of the base.

Residual Layer Removal Step

The cured product 109 left on the base 102 after the separation step has a structure corresponding to the pattern of the mold 104 and can have a residual layer RL at the bottom of the recessed portion. FIG. 3G schematically illustrates the residual layer removal step of removing the residual layer RL. In the residual layer removal step, the cured product 109 and the adhesion layer 101 are etched so as to expose the adhesion layer 101 under the recessed portion of the cured product 109 and further expose the base 102, leaving the cured product pattern 111 corresponding to the protruding portion of the cured product 109 and the adhesion layer 101 below that. In this way, an article having the cured product pattern 111 can be produced.

As a method for removing the residual layer RL and the adhesion layer 101 below that, for example, a method can be employed in which the entire region of the cured product 109 is etched so as to remove the residual layer RL and the adhesion layer 101. The method for removing the residual layer RL at the bottom of the recessed portion of the cured product 109 and the adhesion layer 101 below that is not particularly limited. For example, dry etching can be employed. For the dry etching, a dry-etching apparatus can be used. A source gas for the dry etching can be appropriately selected in accordance with the elemental composition of the cured product 109 to be etched. Examples of the source gas include halogenated gases such as CF₄, C₂F₆, C₃F₈, CCl₂F₂, CCl₄, CBrF₃, BCl₃, PCl₃, SF₆, and Cl₂. Further examples of the source gas include oxygen-containing gases such as O₂, CO, and CO₂, inert gases such as He, N₂, and Ar, H₂ gas, and NH₃ gas. These source gases may be used in combination as a mixture.

It is possible to obtain a structure (article) in which the cured product pattern 111 is disposed on the base 102 with the adhesion layer 101 provided therebetween through the foregoing steps. The structure can be used, for example, as the whole or part of an optical component such as a diffraction grating and a polarizer.

Processing Step

The structure that has been subjected to the residual layer removal treatment can be subjected to the processing step. FIG. 3H schematically illustrates the processing step. The cured product pattern 111 can be used as an interlayer insulating film for an electronic component such as a semiconductor device. In this case, a film such as a conductive film or an insulating film can be disposed on the interlayer insulating film. The cured product pattern 111 may be used as a mask to process the base 102. For example, the base 102 may be subjected to etching or ion implantation with the cured product pattern 111 as a mask. In an example of the etching of the base 102, a portion of the base 102 to be etched may be the semiconductor substrate or a layer such as a conductive layer or an insulating layer disposed on the semiconductor substrate. Etching the base 102 enables the formation of the pattern structure 113. Examples of the semiconductor device can include, but are not limited to, LSI circuits, system LSI circuits, DRAMs, SDRAMs, RDRAMs, and D-RDRAMs.

After the processing step illustrated in FIG. 3H, the base 102 can be further processed to form a semiconductor device substrate including at least one semiconductor chip. The semiconductor device substrate can be subjected to dicing to form the semiconductor chip. The semiconductor chip can be mounted on a wiring board such as a PCB to produce an electronic device (for example, a display, a camera, or medical equipment).

The base 102 can be subjected to, for example, etching or ion implantation using the cured product pattern 111 as a mask to provide, for example, an optical component, a microfluidic flow-channel structure, or a patterned medium.

The whole or part of the cured product pattern 111 may be removed or left in the production process.

### EXAMPLES

While examples of the present invention will be described below, the technical scope of the present invention is not limited to the following examples. In the following description, “part(s)” and “%” are on a weight basis unless otherwise specified.

(1) Evaluation of Polymerization Inhibition Effect with Polymerization Inhibitor

A polymerization inhibition effect with a polymerization inhibitor was evaluated by a method described below.

(1-1) Preparation of Radical Polymerizable Composition

A compound (a), a compound (g), and a polymerization inhibitor (B) described below were mixed. As presented in Table 1, compositions containing the compound (a) and different types and concentrations of the polymerization inhibitor (B) were prepared. Here, at a concentration of the polymerization inhibitor (B) of more than 10 parts by weight, it is not uniformly dissolved, thereby disadvantageously resulting in a portion where an adhesion layer, which is formed by bonding a base to the curable base material by heating, is not formed. Thus, the upper limit of the concentration of the polymerization inhibitor (B) was 10 parts by weight.

A polymerization inhibitor (for example, 4-methoxyphenol) is commonly added to a radical polymerizable compound such as a (meth)acrylate compound in advance in an amount of about 100 ppm when shipped from a raw-material manufacturer. In the case where the (meth)acrylate compound is used as the compound (a) of the present invention, the added polymerization inhibitor is not removed before use.

### (Compound (a)): 100 Parts by Weight in Total

(a-1) Benzyl acrylate (trade name: V#160, available from Osaka Organic Chemical Industry Ltd.)
(a-2) Isobornyl acrylate (trade name: Light Acrylate IB-XA, available from Kyoeisha Chemical Co., Ltd.)
(a-3) Neopentyl glycol diacrylate (trade name: Light Acrylate NP-A, available from Kyoeisha Chemical Co., Ltd.)

### (Compound (g)): 0.1 Parts by Weight

(g-1) Lucirin TPO (available from BASF)

### (Polymerization Inhibitor (B))

(B-1) 4-Methoxyphenol (abbreviated as MEHQ, available from Tokyo Chemical Industry Co., Ltd.)
(B-2) Phenothiazine (abbreviated as PTZ, available from Tokyo Chemical Industry Co., Ltd.)

TABLE 1

| | Compound (a) | | Polymerization | |
|---|---|---|---|---|
| | | Parts | inhibitor (B) | |
| | Material | by weight | Material | Parts by weight |
| Composition 1 | mixture of | 100 | no | 0 |
| Composition 2 | a-1, | | B-1 | 0.1 |
| Composition 3 | a-2, and | | B-1 | 0.2 |
| Composition 4 | a-3 | | B-1 | 1 |
| Composition 5 | | | B-1 | 10 |
| Composition 6 | | | B-2 | 0.1 |
| Composition 7 | | | B-2 | 0.2 |
| Composition 8 | | | B-2 | 1 |
| Composition 9 | | | B-2 | 2 |
| Composition 10 | | | B-2 | 5 |

(1-2) Evaluation of Polymerization Inhibition Effect

The half decay exposure of each of the compositions 1 to 10 prepared in (1-1) was measured with the attenuated total reflection infrared spectrometer 200 including the light irradiation portion. The gel particle formation rate can be considered to be proportional to the reciprocal of the half decay exposure. The reciprocals of the half decay exposure values of the compositions 1 to 10 are converted into relative values (relative particle formation rates) with respect to 100 of the reciprocal of the half decay exposure of the composition 1 and are presented in Table 2 and FIG. 5.

TABLE 2

| | Polymerization inhibitor (B) | | Relative particle |
|---|---|---|---|
| | Material | Parts by weight | formation rate |
| Composition 1 | no | 0 | 100 |
| Composition 2 | B-1 | 0.1 | 90 |
| Composition 3 | B-1 | 0.2 | 73 |
| Composition 4 | B-1 | 1 | 55 |
| Composition 5 | B-1 | 10 | 22 |
| Composition 6 | B-2 | 0.1 | 49 |
| Composition 7 | B-2 | 0.2 | 43 |
| Composition 8 | B-2 | 1 | 30 |
| Composition 9 | B-2 | 2 | 12 |
| Composition 10 | B-2 | 5 | 6 |

The composition 1 is a composition free from the polymerization inhibitor (B). The compositions 2 to 5 are compositions containing B-1 serving as the polymerization inhibitor (B). These results indicate that the use of a larger amount of B-1 in the composition is seemingly effective in inhibiting the polymerization to reduce the particle formation rate. In the composition 2 containing 0.1 parts by weight B-1, the effect of reducing the particle formation rate by about 10% with respect to the composition 1 is provided. In other words, at less than 0.1 parts by weight, there is no effect of clearly reducing the particle formation rate. Based on 100 parts by weight of the compound (A), the use of a B-1 content of 0.1 parts by weight or more is effective in inhibiting the particle formation.

The results presented in Table 2 and FIG. 5 indicate that the use of a B-1 content of 2 parts by weight or more is effective in reducing the particle formation rate to 50% or less.

The compositions 6 to 10 are compositions containing B-2 serving as the polymerization inhibitor (B). These results indicate that the use of a larger amount of B-2 in the composition is seemingly effective in inhibiting the polymerization to reduce the particle formation rate. Regarding the effect provided by the addition of the polymerization inhibitor, the addition of B-2 is more effective than that of B-1. The use of a B-2 content of 0.1 parts by weight or more based on 100 parts by weight of a curable base material (A) is effective in reducing the particle formation rate to about 50% or less.

(2) Formation of Adhesion Layer-Forming Composition

(2-1) Preparation of Adhesion Layer-Forming Composition

A curable base material (A), a polymerization inhibitor (B), an organic solvent (C), a crosslinker (D), and another component (E) described below were mixed together to form adhesion layer-forming compositions.

As presented in Table 3, adhesion layer-forming compositions containing different types and concentrations of the polymerization inhibitor (B) were prepared. Each of the resulting adhesion layer-forming compositions was then filtered with a polytetrafluoroethylene filter having a pore size of 0.2 μm, thereby preparing compositions 11 to 20 as presented in Table 3.

### (Curable Base Material (A))

(A-3) Multifunctional compound (trade name: Isorad501, available from Schenectady International, Inc.)

### (Polymerization Inhibitor (B))

(B-1) 4-Methoxyphenol (available from Tokyo Chemical Industry Co., Ltd.)
(B-2) Phenothiazine (available from Tokyo Chemical Industry Co., Ltd.)

### (Solvent (C))

Propylene glycol monomethyl ether acetate (available from Tokyo Chemical Industry Co., Ltd.)

### (Crosslinker (D))

Hexamethoxymethylmelamine (trade name: Cymel 303ULF, available from Cytec Industries, Inc.)
(Another component (E))
Catalyst (trade name: Cycat 4040, available from Cytec Industries, Inc.)

TABLE 3

| | Polymerization inhibitor (B) | |
|---|---|---|
| | Material | Parts by weight |
| Composition 11 | no | 0 |
| Composition 12 | B-1 | 0.1 |
| Composition 13 | B-1 | 0.2 |
| Composition 14 | B-1 | 1 |
| Composition 15 | B-1 | 10 |
| Composition 16 | B-2 | 0.1 |
| Composition 17 | B-2 | 0.2 |
| Composition 18 | B-2 | 1 |
| Composition 19 | B-2 | 2 |
| Composition 20 | B-2 | 5 |

The composition 11 is a comparative example. Also in the compositions 12 to 20, the gel particle formation rates should be reduced by the polymerization inhibition effect with the polymerization inhibitor.

(3) Evaluation of Curability

The curability of the adhesion layer-forming compositions is evaluated by a method described below.

(3-1) Formation of Adhesion Layer

Each of the compositions 11 to 20 prepared in (2-1) is applied to a silicon wafer by spin coating. The spin coating is performed at 3,000 rpm for 30 seconds. Each composition is then heated on a hot plate to form an adhesion layer.

(3-2) Evaluation of Curability

The curability is evaluated as follows: A surface of the adhesion layer formed in (3-1) is wiped with a Bemcot wiper wetted with acetone. The adhesion layer is visually checked for dissolution or peeling. Good results are obtained in any of the compositions.

(4) Evaluation of Adhesion

The adhesion between a base and a cured film obtained by curing a photocurable composition is evaluated by a method described below.

(4-1) Preparation of Photocurable Composition

A component (F), a component (G) (photopolymerization initiator), and another additive component (H), which are described below, are mixed to prepare a mixed solution.

The resulting mixed solution is then filtered with a filter that is composed of an ultrahigh-molecular-weight polyethylene and that has a pore size of 0.2 μm, thereby preparing a photocurable composition.

### (Component (F): Polymerizable Compound)

(F-1) Isobornyl acrylate (trade name: IB-XA, available from Kyoeisha Chemical Co., Ltd.)
(F-2) Benzyl acrylate (trade name: V#160, available from Osaka Organic Chemical Industry Ltd.)
(F-3) Neopentyl glycol diacrylate (trade name: NP-A, available from Kyoeisha Chemical Co., Ltd.)
(F-4) Dimethyloltricyclodecane diacrylate (trade name: DCP-A, available from Kyoeisha Chemical Co., Ltd.)

### (Component (G): Photopolymerization Initiator)

(G-1) Lucirin TPO (available from BASF)

### (Another Additive Component (H))

(H-1) 4,4′-Bis(diethylamino)benzophenone (available from Tokyo Chemical Industry Co., Ltd.)
(H-2) Polyoxyethylene stearyl ether, Emulgen 320P (available from Kao Corporation)

(4-2) Formation of Adhesion Layer

Each of the compositions 11 to 20 prepared in (2-1) is applied to a silicon wafer by spin coating. The spin coating is performed at 3,000 rpm for 30 seconds. Each composition is then heated on a hot plate to form an adhesion layer. In this way, the adhesion layers having a thickness of 10 nm or less are formed.

(4-3) Curing of Photocurable Composition

First, 2 μL of the photocurable composition prepared in (4-1) is disposed by dropping on the adhesion layer formed on the silicon wafer in (4-2). Quartz glass having a thickness of 1 mm is disposed thereon to fill a region measuring 35 mm×25 mm with the photocurable composition.

The photocurable composition is irradiated with light for 200 seconds, the light being emitted from an UV-light source equipped with an ultrahigh-pressure mercury lamp and passing through an interference filter described below and then the quartz glass. Thereby, the photocurable composition is cured to form a cured film. The interference filter used for the light irradiation is VPF-25C-10-15-31300 (available from Sigmakoki Co., Ltd). The irradiation light used is ultraviolet light having a single wavelength of 313±5 nm and an illuminance of 1 mW/cm².

(4-4) Evaluation of Adhesion

After the photocuring, the quartz glass is peeled and visually checked for the presence or absence of the peeling of the cured film from the base. In any of the examples, the cured film is not peeled in the entire region measuring 35 mm×25 mm.

That is, even when the adhesion layer-forming composition contains 0.1 parts by weight of the polymerization inhibitor based on 100 parts by weight of the compound (A) component, the adhesion is not adversely affected because the composition is heated to form the adhesion layer.

The present invention is not limited to the foregoing embodiments. Various changes and modification can be made without departing from the spirit and scope of the present invention. To publicize the scope of the present invention, thus, the following claims are attached.

According to the present invention, the adhesion layer composition that is advantageous in reducing the formation of particles due to a spontaneous polymerization reaction is provided.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

1. An adhesion layer-forming composition to allow a substrate to adhere to a photocurable composition, the adhesion layer-forming composition at least comprising:
a curable base material (A) containing at least one functional group that binds to a base and at least one radically polymerizable functional group;
a polymerization inhibitor (B); and
an organic solvent (C),
the adhesion layer-forming composition having a polymerization inhibitor (B) content of 0.1 parts by weight or more and 20 parts by weight or less based on 100 parts by weight of the curable base material (A).

2. The adhesion layer-forming composition according to claim 1, wherein the polymerization inhibitor (B) is at least one selected from phenolic compounds, quinone-based compounds, N-oxyl-based compounds, and amine-based compounds.

3. The adhesion layer-forming composition according to claim 1, wherein the polymerization inhibitor (B) is one of hydroquinones, catechols, phenothiazine, and phenoxazine.

4. The adhesion layer-forming composition according to claim 3, wherein the adhesion layer-forming composition has a polymerization inhibitor (B) content of 2 parts by weight or more and 10 parts by weight or less based on 100 parts by weight of the curable base material (A).

5. The adhesion layer-forming composition according to claim 1, further comprising a crosslinker (D) that forms a crosslinked structure by reacting with the curable base material (A) to bond molecules of the curable base material (A) together at a heating temperature of 70° C. or higher and 280° C. or lower, preferably 100° C. or higher and 265° C. or lower, more preferably 140° C. or higher and 250° C. or lower.

6. The adhesion layer-forming composition according to claim 5, wherein the crosslinker (D) also reacts with the polymerization inhibitor (B) at a heating temperature of 70° C. or higher and 280° C. or lower, preferably 100° C. or higher and 265° C. or lower, more preferably 140° C. or higher and 250° C. or lower to eliminate a polymerization inhibiting effect of the polymerization inhibitor (B).

7. The adhesion layer-forming composition according to claim 5, wherein the crosslinker (D) is at least one selected from melamine-based compounds and urea-based compounds.

8. The adhesion layer-forming composition according to claim 1, wherein the adhesion layer-forming composition is used in photo-imprinting.

9. A method for producing an article, comprising:
a first step of disposing the adhesion layer-forming composition according to claim 1 on a base to form an adhesion layer;
a second step of disposing a photocurable composition on the base including the adhesion layer;
a third step of bringing the photocurable composition into contact with a mold having a pattern;
a fourth step of irradiating the photocurable composition with light to form a cured product; and
a fifth step of separating the cured product from the mold.

10. The method for producing an article according to claim 9, wherein the first step is a step of disposing the adhesion layer-forming composition on the base having a hydroxy group on a surface thereof.

11. The method for producing an article according to claim 9, wherein the first step includes a heating step, wherein a concentration of the polymerization inhibitor (B) in the adhesion layer is less than 0.1 parts by weight by allowing the polymerization inhibitor (B) to react with a crosslinker (D) in the heating step.

12. The method for producing an article according to claim 9, wherein the second step is performed in an atmosphere containing a condensable gas.

13. The method for producing an article according to claim 9, wherein an optical component including the cured product is produced.

14. The method for producing an article according to claim 9, further comprising a processing step of subjecting the base to etching or ion implantation using the cured product as a mask.

15. The method for producing an article according to claim 14, further comprising the steps of:
after the processing step, further processing the base to provide a semiconductor chip; and
mounting the semiconductor chip on a wiring board.
